(19) United States
(12) Patent Application Publication
(10) Pub. No.: US 2015/0357280 A1
(43) Pub. Date: Dec. 10, 2015

(54) MEMORY CARD AND METHOD FOR MANUFACTURING THE SAME

(71) Applicant: Kabushiki Kaisha Toshiba, Minato-ku (JP)

(72) Inventors: Akihiro IIDA, Kamakura (JP); Taku NISHIYAMA, Yokohama (JP)

(73) Assignee: Kabushiki Kaisha Toshiba, Minato-ku (JP)

(21) Appl. No.: 14/482,253

(22) Filed: Sep. 10, 2014

Related U.S. Application Data
(60) Provisional application No. 62/008,970, filed on Jun. 6, 2014.

(51) Int. Cl. H01L 23/528; H01L 21/56; H01L 21/48; H01L 23/31

(52) U.S. Cl. CPC H01L 23/528; H01L 23/3114; H01L 21/561; H01L 21/4853

(57) ABSTRACT

According to one embodiment, a memory card is disclosed. The memory card includes a substrate, a memory provided on the substrate, a controller provided on the substrate, and a first interconnect provided on the substrate. A distance between an edge of the substrate and the first interconnect is greater than or equal to 0.4 mm. The memory card further includes a resin covering the memory, the controller and the interconnect. The resin includes a first region and a second region, the amount of carbide in the first region is larger than the amount of carbide in the second region.

### CROSS-REFERENCE TO RELATED APPLICATIONS

This application claims the benefit of U.S. Provisional Application No. 62/008,970, filed Jun. 6, 2014, the entire contents of which are incorporated herein by reference.

### FIELD

Embodiments described herein relate generally to a memory card and a method for manufacturing the same.

### BACKGROUND

As one of semiconductor packages, a type is known, in which semiconductor chips with different functions are enclosed in one package (SiP (system in package)).

### BRIEF DESCRIPTION OF THE DRAWINGS

FIG. 1 is a schematic view of an external form of a memory card according to an embodiment;

FIG. 2 is a cross-sectional view showing a structure of a semiconductor storage device in the memory card according to an embodiment;

FIG. 3 is a cross-sectional view showing another configuration of the semiconductor storage device in the memory card according to an embodiment;

FIG. 4 is a flowchart showing a method for manufacturing the memory card according to an embodiment;

FIG. 5 is a plan view showing a substrate including a plurality of interconnect substrate regions;

FIG. 6 is a schematic view showing an example of an interconnect structure formed in an interconnect substrate region;

FIG. 7 is a view showing a contour of the interconnect substrate according to an embodiment;

FIG. 8 is an enlarged view of a part of the contour in FIG. 7 and an interconnect structure around the part;

FIG. 9 is a view illustrating irradiation position of laser light;

FIG. 10 is a view showing an evaluation result of leakage occurrence rate for condition 1;

FIG. 11 is a view showing an evaluation result of the leakage occurrence rate for condition 2;

FIG. 12 is a view showing an evaluation result of the leakage occurrence rate for condition 3;

FIG. 13 is a view showing an evaluation result of the leakage occurrence rate for condition 4;

FIG. 14 is a view showing the Weibull distribution of distance D and the leakage occurrence rate with respect to each of conditions 1 to 4; and

FIG. 15 is a plan view illustrating an upper limit of distance D of the interconnect substrate.

### DETAILED DESCRIPTION

In general, according to one embodiment, a memory card is disclosed. The memory card includes a substrate; a memory provided on the substrate; a controller provided on the substrate; and a first interconnect provided on the substrate. A distance between an edge of the substrate and the first interconnect is greater than or equal to 0.4 mm. The memory card further includes a resin covering the memory, the controller and the interconnect. The resin includes a first region and a second region, the amount of carbide in the first region is larger than the amount of carbide in the second region.

In general, according to one embodiment, a method for manufacturing a memory card is disclosed. The method includes forming a resin on a substrate; and dividing the resin and the substrate into a plurality of resins and a plurality of substrates, respectively, by using laser irradiation and blade. The plurality of resins and the plurality of substrates includes a first resin and a first substrate, respectively, a distance between an edge of the first substrate and first area is greater than or equal to 0.4 mm.

Various embodiments will be described hereinafter with reference to the accompanying drawings. In the drawings, the same portions are denoted by the same reference numbers. The overlapping descriptions are provided as necessary.

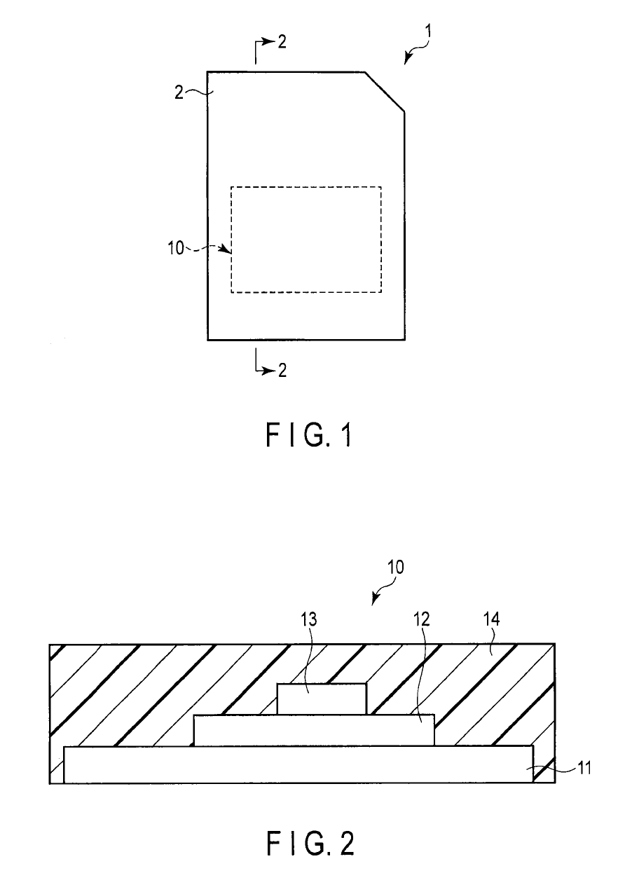

FIG. 1 is a plan view showing an external form of a memory card according to an embodiment. FIG. 2 is a 2-2 cross-sectional view of FIG. 1.

Memory card 1 of the present embodiment is used as a memory card conforming to the SD™ standard (SD™ card). Memory card 1 comprises a case 2 and a semiconductor storage device 10 of SiP (System in Package) structure accommodated in the case 2. Semiconductor storage device 10 includes an interconnect substrate, semiconductor chips with different functions formed on the interconnect substrate, and a resin layer which seals the semiconductor chips.

As shown in FIG. 2, the semiconductor storage device 10 comprises an interconnect substrate 11, a NAND flash memory (nonvolatile memory) 12 provided on the interconnect substrate 11, and a controller 13 provided on the NAND flash memory 12. The controller 13 controls the NAND flash memory 12. Another nonvolatile memory such as an MRAM (nonvolatile magnetic memory), etc., may be used instead of the NAND flash memory 12 (nonvolatile semiconductor memory).

The semiconductor storage device 10 further comprises a molding resin 14 which seals the interconnect substrate 11, the NAND flash memory 12 and the controller 13. In the present embodiment, molding resin 14 includes molten silica. The concentration of molten silica is, for example, 75 to 95% by weight.

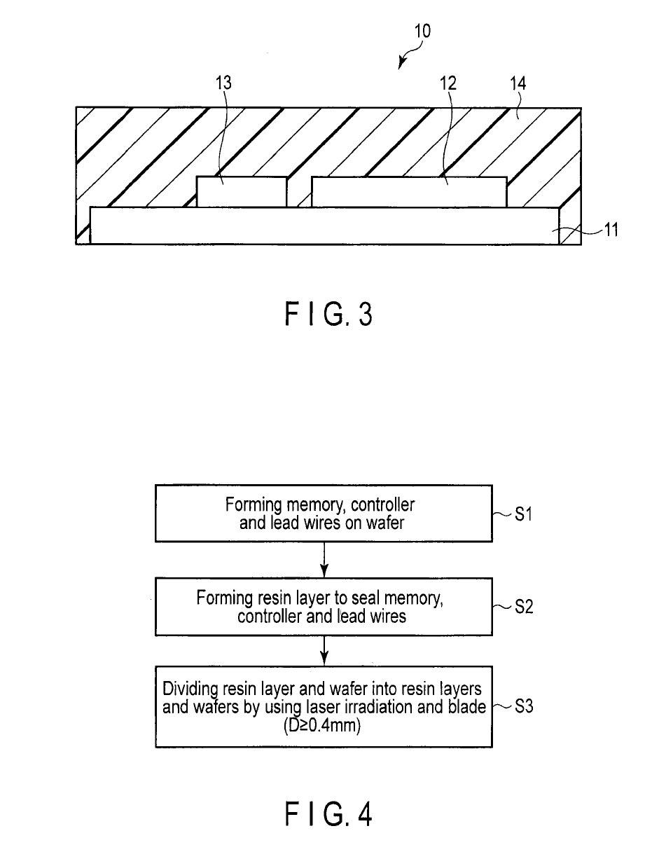

FIG. 2 shows a stack type semiconductor storage device of SiP structure, but a side-by-side type semiconductor storage device of SiP structure shown in FIG. 3 may also be employed.

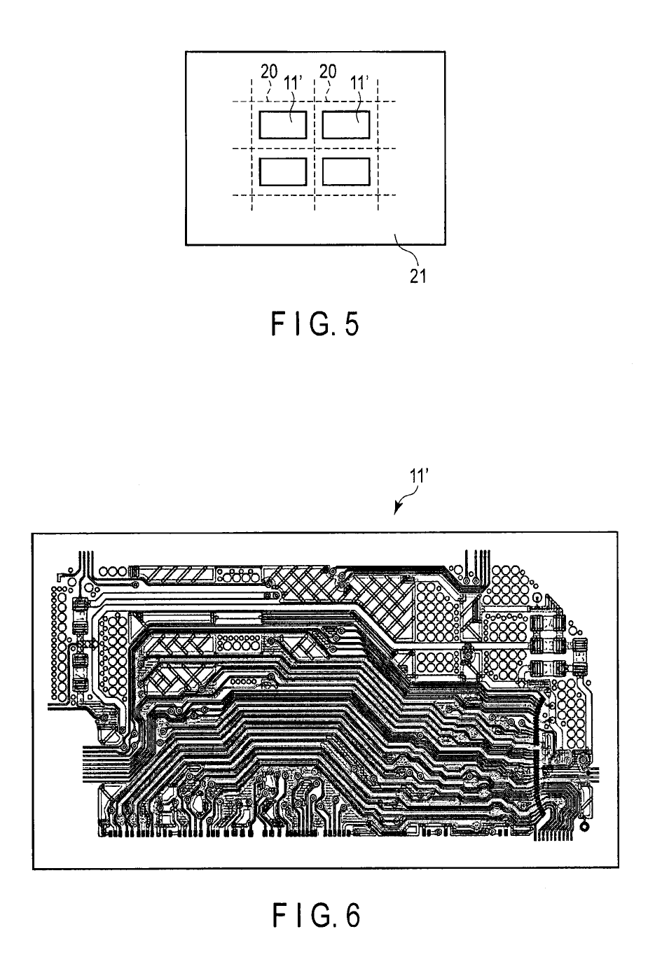

An example of a method for manufacturing the semiconductor storage device of the memory card of the present embodiment will be described with reference to a flowchart in FIG. 4 and a plan view in FIG. 5.

The above-described memory, the controller and interconnect substrate 11′ including lead wires are formed in each of a plurality of interconnect substrate regions 20 on insulating substrate 21 (step S1). A material of substrate 21 is, for example, a glass epoxy resin. FIG. 6 schematically shows an example of the interconnect structure of interconnect substrate 11′ at the stage of FIG. 5.

The resin layer is formed on substrate 21 to seal the memories, the controllers and the lead wires on interconnect substrate regions 20 (step S2).

The resin layer and substrate 21 are processed by means of cutting by laser irradiation (laser processing) and cutting by blade (blade processing), and thereby divided into a plurality of resin layers and a plurality of interconnect substrates, respectively (step S3). Such a method of forming the plurality of interconnect substrates at the same time has higher manufacturing efficiency than a method of individually forming the plurality of interconnect substrates.

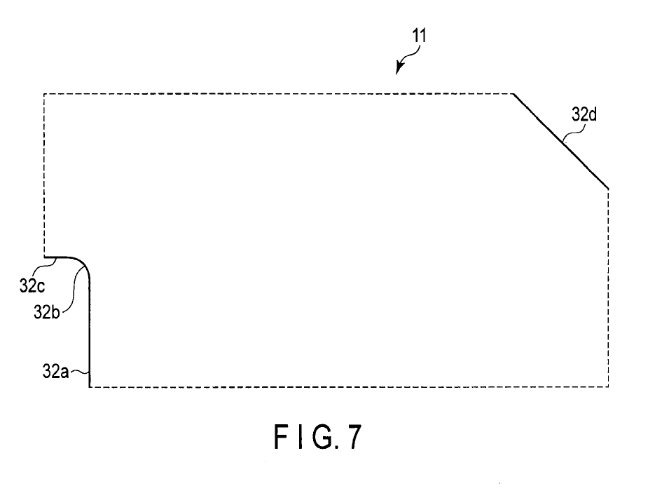

When the interconnect substrate 11′ of FIG. 6 is cut by the laser processing and the blade processing, interconnect substrate 11 having a contour, for example, shown in FIG. 7 can be obtained. In FIG. 7, the contour is represented by solid lines and broken lines. The solid lines represent a portion subjected to the laser processing, and the broken lines represent a portion subjected to the blade processing portion.

Of the contour defining the external form of the interconnect substrate 11, the portion cut by laser processing includes a line 32a (first line) perpendicular to the longitudinal direction of the interconnect substrate 11, curved line 32b connected to the line 32a, and a line 32c parallel with the longitudinal direction of the interconnect substrate 11 and connected to the second line 32b. The portion cut by laser processing further includes a line 32d inclined approximately 45° toward the longitudinal direction of the interconnect substrate 11. The inclination of the line 32d is not limited to 45°.

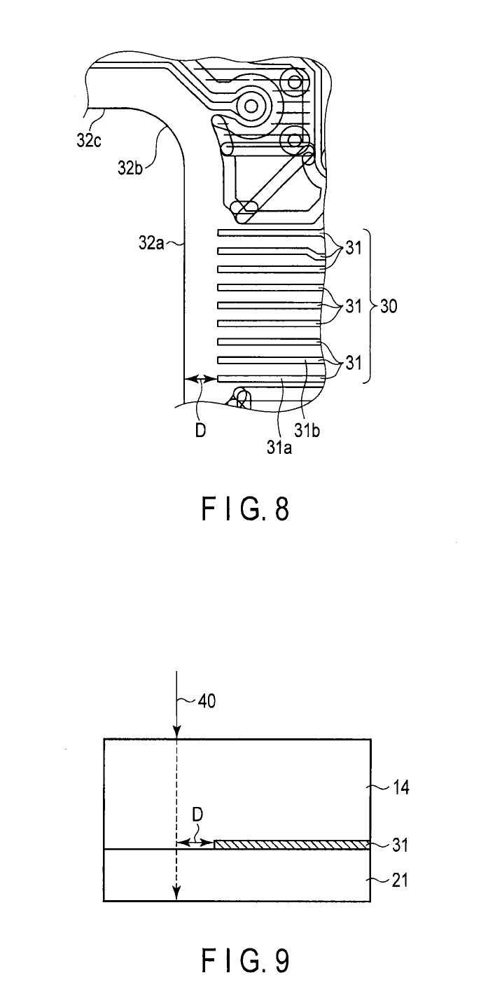

FIG. 8 is an enlarged view of lines 32a, 32b and 32c of FIG. 7, and the interconnect structure around the lines. In the drawing, 30 represents an interconnect group. The interconnect group 30 includes a plurality of lead wires 31. FIG. 7 shows eight (first to eighth) lead wires 31, but the number of lead wires 31 is not limited to this. Lead wires 31 are, for example, plated wires formed by plating. A metallic material of leads 31 is, for example, copper (Cu).

In the present embodiment, the resin layer and the substrate are divided into the plurality of resin layers and the plurality of substrates in step S3 such that a distance D between the lead wire and a line perpendicular to the longitudinal direction of the lead wire (a first line (corresponding to line 32a in FIG. 7)) among the lines constituting the contour defining the external shape of the portion cut by laser irradiation is greater than or equal to 0.4 mm. The side surface of the resin layer on the first line is subjected to the laser processing. The side surface of the resin layer on the broken line (second line) of FIG. 6 is subjected to the blade processing.

The distance D between line 32a and lead 31 is greater than or equal to 0.4 mm. This is because, the intensive study by the inventors revealed that a short circuit (occurrence of a leakage current) between adjacent leads 31 (for example, leads 31a and 31b in FIG. 8) can be prevented if D ≧0.4 mm.

The molding resin 14 is irradiated with a laser light and heated at the time of the laser processing. Since molding resin 14 includes silica (SiO2) and carbon (C), a compound of silicon and carbon is formed by the above heating, and carbide (SiC) is thereby generated in molding resin 14. If the carbide is generated between adjacent leads 31 (for example, leads 31a and 31b in FIG. 7) in molding resin 14, the short circuit (leakage current) occurs between adjacent leads 31.

At the time of the laser processing, an upper surface of molding resin 14 is first irradiated with a laser light 40 as shown in FIG. 9. The portion irradiated with the laser light 40 absorbs energy of the laser light 40, is heated, molten and evaporates. The portion exposed by the evaporation is irradiated with the laser light 40, and the portion irradiated with the laser light 40 evaporates in the same manner. Cutting by laser processing proceeds by repeating the above procedure. Therefore, in the case of FIG. 9, the cutting proceeds in the order of the molding resin 14, the substrate 21 along the direction of a dashed arrow.

In the case of FIG. 8, the larger the distance D is, the leads 31 are further away from the irradiation position of the laser light, and the smaller the amount of absorbed energy of the laser light becomes, so that the carbide of molding resin entering between adjacent leads 31 is considered to have a smaller influence.

When the distance D is constant, there is a possibility that the energy density of the laser light influences on the carbonization of molding resin 14.

Furthermore, when the distance D and the energy density are constant, there is a possibility that the number of cuts (the number of irradiations) by the laser light influences on the carbonization of molding resin 14.

Therefore, an occurrence rate of the leakage current (leakage occurrence rate) is evaluated by varying the number of cuts, the energy intensity per cut, and the distance D as parameters. The distance D can be measured by using X-ray. Moreover, for convenience of the measurement, the laser irradiation is performed by using a laser equipment configured to perform irradiation by selecting either a laser light having a first wavelength (1064 nm) or a laser light having a second wavelength (532 nm). A laser equipment configured to perform irradiation by selecting an arbitrary one of three or more laser lights having different wavelengths may also be used.

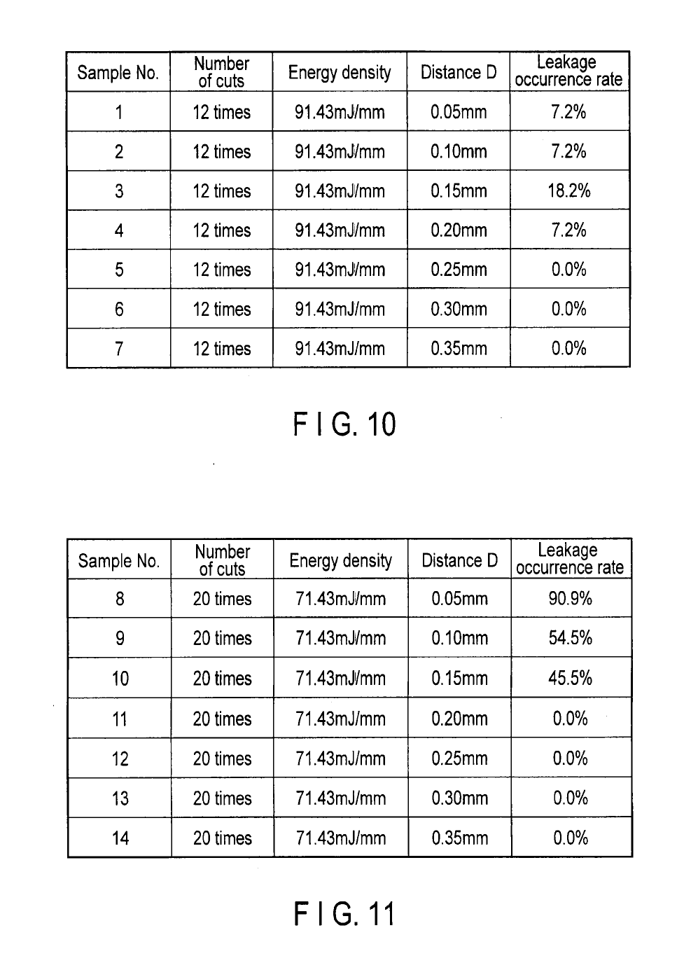

FIG. 10 to FIG. 13 show evaluation results of twenty eight samples.

Seven samples (first sample group) in FIG. 10 show a sample evaluation result (evaluation result 1) obtained when the distance D (0.05 to 0.35 mm) is varied on the condition that the number of cuts is 12 and the energy intensity per cut is 91.43 mJ/mm (condition 1).

Seven samples (second sample group) in FIG. 11 show a sample evaluation result (evaluation result 2) obtained when the distance D (0.05 to 0.35 mm) is varied on the condition that the number of cuts is 20 and the energy intensity per cut is 71.43 mJ/mm (condition 2).

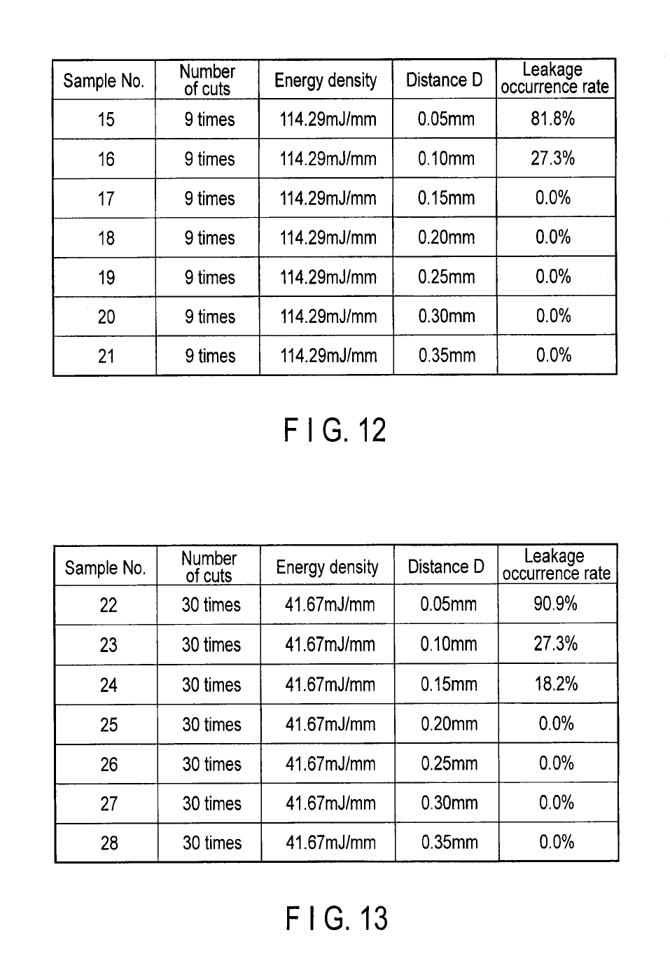

Seven samples (third sample group) in FIG. 12 show a sample evaluation result (evaluation result 3) obtained when the distance D (0.05 to 0.35 mm) is varied on the condition that the number of cuts is 9 and the energy intensity per cut is 114.29 mJ/mm (condition 3).

Seven samples (fourth sample group) in FIG. 13 show a sample evaluation result (evaluation result 4) obtained when the distance D (0.05 to 0.35 mm) is varied on the condition that the number of cuts is 30 and the energy intensity per cut is 41.67 mJ/mm (condition 4).

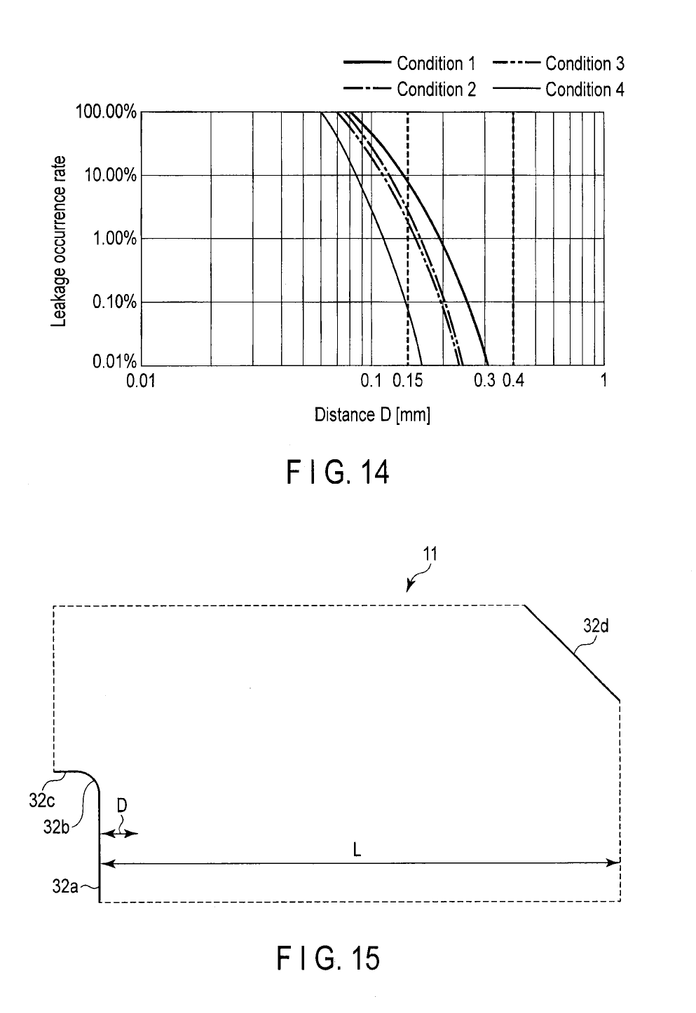

FIG. 14 shows the Weibull distribution of the distance D and the leakage occurrence rate with respect to each of the above-described conditions 1 to 4 prepared based on the above-described evaluation results 1 to 4. The leakage occurrence rate which are not shown in FIG. 10 to FIG. 13 are obtained by, for example, interpolation.

From FIG. 14, it is appreciated that the distance D is required to be 0.3 mm or more for setting the leakage occurrence rate to 0.01% (100 ppm) or less.

Here, a tolerance of lead wire 31 is typically ±0.05 mm, a tolerance of the laser machining is typically ±0.07 mm, and a square root of a sum of squares of the tolerances squared (square root of a sum of squares of the respective tolerances) (0.05² +0.072)^{½} is approximately 0.39, hence the distance D is set greater than or equal to 0.4 mm.

According to an inspection of the memory device of the embodiment (D ≧0.4 mm), the leakage current flowing between adjacent leads 31 is not detected. Furthermore, according to a component analysis of molding resin layer 14 of semiconductor storage device 10 of the embodiment, carbide is detected on interconnect substrate 11 where the distance D <0.4 mm, but is not detected on interconnect substrate 11 where the distance D ≧0.4 mm. That is, the carbide which causes the leakage current by short-circuiting between adjacent leads 31 is not detected. As shown in FIG. 14, since the leakage occurrence rate is sufficiently low in each of conditions 1 to 4 if D ≧0.4 mm, there is no upper limit to distance D from the viewpoint of lowering the leakage occurrence rate. However, in the case of interconnect substrate 11 shown in FIG. 7, since the dimension L of interconnect substrate 11 in the longitudinal direction is, for example, 19.15 ±0.1 mm, the upper limit of the distance D is 19.25 mm.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory card comprising:
a substrate;
a memory provided on the substrate;
a controller provided on the substrate;
a first interconnect provided on the substrate, a distance between an edge of the substrate and the first interconnect being greater than or equal to 0.4 mm; and
a resin covering the memory, the controller and the interconnect, the resin including a first region and a second region, the amount of carbide in the first region being larger than the amount of carbide in the second region.

2. The card of claim 1, wherein the first region is between the edge and the first interconnect, and the second region is on the first interconnect.

3. The memory card of claim 1, further comprising a second interconnect arranged next to the first interconnect, wherein a distance between the edge and the second interconnect is greater than or equal to 0.4 mm.

4. The card of claim 3, wherein the resin on the second interconnect does not include carbide.

5. The card of claim 1, wherein the resin includes molten silica.

6. A memory card comprising:
a substrate;
a memory provided on the substrate;
a controller provided on the substrate;
a first interconnect provided on the substrate, a distance between an edge of the substrate and the first interconnect being greater than or equal to 0.4 mm; and
a resin covering the memory, the controller and the interconnect, the resin comprising a first portion having a distance from the edge is greater than or equal to a first value, and a second portion having a distance from the edge is less than the first value, a density of carbide included in the first portion is less than a density of carbide included in the second portion.

7. The card of claim 6, wherein the first value is 0.4 mm.

8. A method for manufacturing a memory card comprising:
forming a resin on a substrate; and
dividing the resin and the substrate into a plurality of resins and a plurality of substrates, respectively, by using laser irradiation and blade, the plurality of resins and the plurality of substrates including a first resin and a first substrate, respectively, a distance between an edge of the first substrate and first area being greater than or equal to 0.4 mm.

9. The method of claim 8, further comprising:
forming a first interconnect on the first area of the substrate.

10. The method of claim 9, wherein the forming the first interconnect on the substrate further comprises forming a second interconnect on the substrate, which is arranged next to the first interconnect, and wherein a distance between the edge and the second interconnect is greater than or equal to 0.4 mm.

11. The method of claim 8, wherein the edge includes a first line, a distance between the first line and the first interconnect is greater than or equal to 0.4 mm, and a side surface of the resin on the first line is processed by laser irradiation.

12. The method of claim 8, wherein the laser irradiation is performed by using a laser equipment capable of selecting an arbitrary one among a plurality of laser lights with a plurality of different wavelengths including a laser light with a first wavelength and a laser light with a second wavelength different from the first wavelength, and capable of irradiating the arbitrary one.

13. The method of claim 12, wherein the first wavelength is twice the second wavelength.

14. The method of claim 8, further comprising:
forming a memory and a controller on the substrate.
